(19) United States
(12) Patent Application Publication
(10) Pub. No.: US 2010/0283386 A1
(43) Pub. Date: Nov. 11, 2010

(54) DISPLAY DEVICE AND COMPOSITION FOR PRODUCING DISPLAY DEVICE, AND DISPLAY DEVICE

(75) Inventors: Masakazu Muroyama, Kanagawa (JP); Ichiro Saito, Kanagawa (JP); Hiroaki Usui, Tokyo (JP); Seiji Yokokura, Tokyo (JP)

Correspondence Address: K&L Gates LLP, P. O. BOX 1135, CHICAGO, IL, 60690, US

(73) Assignees: SONY CORPORATION, Tokyo (JP); NATIONAL UNIVERSITY CORPORATION, Tokyo (JP)

(21) Appl. No.: 12/812,417

(22) PCT Filed: Dec. 19, 2008
(86) PCT No.: PCT/JP2008/073892

§ 371 Date: Jul. 9, 2010

(30) Foreign Application Priority Data
Jan. 11, 2008 (JP) P2008-004185

(51) Int. Cl. H01J 1/62; H01J 9/00

(52) U.S. Cl. 313/504; 445/24

(57) ABSTRACT

A light-emitting layer is provided between a first electrode and a second electrode. The light-emitting layer is formed through steps of: forming a composition layer including a radical initiator and a light-emitting material having radical-polymerization reactivity; exciting the composition layer to form in the composition layer a polymerized region where the composition layer is polymerized; and removing the composition layer except in the polymerized region.

### CROSS REFERENCE TO RELATED APPLICATIONS

The present application is a National Stage of International Application No. PCT/JP2008/073892 filed on Dec. 19, 2008 and which claims priority to Japanese Patent Application No. 2008-004185 filed on Jan. 11, 2008, the entire contents of which are being incorporated herein by reference.

### BACKGROUND

The present disclosure relates to a display device, a composition for producing a display device, and a display device. The present disclosure more specifically relates to, for example, a method for producing a display device suitable as a large-screen organic EL display, a composition for producing a display device, and a display device.

In recent years, organic EL displays using an organic EL element have attracted increasing attention as display devices to replace liquid crystal displays. An organic EL display is a display of a self-luminous type, in which an organic material itself emits light in response to an electric current passed therethrough. Such an organic EL display thus requires no backlight, and also has advantageous characteristics such as excellent color reproducibility, high contrast, responsiveness suitable for videos, wide viewing angle, etc.

An organic EL display having such advantageous characteristics has ideal properties as a flat-panel display, and with a thickness of not more than 2 mm, a high-resolution, high-visibility 1- to 40-inch display can be realized.

However, combined with the competition with liquid crystal displays, there are issues facing organic EL displays, including application to large-area substrates, reduction in power consumption, improvement of reliability, cost reduction, etc. In particular, the application to large-area substrates has been an extremely important issue. The problem here is the method for producing RGB pixels that emit light of the three primary colors (RGB) to achieve full color display.

As methods for forming RGB pixels, the following methods have been proposed: (1) a separate application method in which RGB-light-emitting layers are two-dimensionally disposed, (2) a color conversion method in which blue light undergoes a fluorescence change, and (3) a color filter method in which white light is divided into the three primary colors using a filter.

The color conversion method of (2) or the color filter method of (3) causes problems of poor color purity, reduced luminance, and the like, and thus does not satisfy the performance of latest display devices. Use of the separate application method of (1) requires, in addition to the reduction of the light-emitting pixel size to microscale, techniques for separate application to form two or more kinds of light-emitting layers on a substrate by means of separate application with high accuracy.

As a technique for the separate application of two or more kinds of light-emitting layers, for example, as described in Japanese Patent No. 2734464, a method in which an organic EL element of the first color is formed through an aperture of a mask, and the mask is then changed so that an organic EL element of the second color is formed through a different aperture has been proposed. This method is simple, but is extremely effective in the production of an organic EL element having multiple color areas.

Further, JP-A-8-227276 proposes a method developed from the method described in Japanese Patent No. 2734464, in which a mask provided with fine apertures at regular intervals is shifted by a pixel pitch every time a light-emitting layer of one color is formed, followed by forming light-emitting layers of the second color and the third color. According to this method, in the case where no organic layer is present between light-emitting layers, an insulating layer plays an important role in preventing a short circuit between the cathode and a transparent electrode and determining the pixel shape.

Further, JP-A-3-105894 proposes a technique in which an ITO film is formed as the anode on a glass substrate, phthalocyanine is formed as a hole injection layer, then an aqueous solution that causes a crosslinking reaction by UV irradiation is applied thereonto by spin coating to form a hole-sensitive light-emitting layer, and UV light is then applied thereto through a negative mask to pattern the light-emitting layer.

Further, JP-A-6-13184 proposes a technique in which at least one layer of the layers forming a light-emitting portion is formed of a photosensitive resin so that patterning can be accomplished using a photosensitive reaction in response to light.

Further, JP-A-10-69981 proposes a technique in which, as a light-emitting layer, a developable photo-curable resin as a matrix material is doped with a hole transport material and/or an electron transport material together with an organic light-emitting material, thereby enabling photolithography patterning of an organic LED (film).

According to the techniques proposed by JP-A-3-105894, JP-A-6-13184, and JP-A-10-69981, taking advantage of the photosensitive properties or heat-curable properties of a resin, an insolubilized region is formed by the addition of a photosensitive matrix material, such as a photosensitive polymer material, whereby the solubility in a solvent is varied to form a pattern.

Further, an ink jet method, in which an organic material solution or RGB dyes are discharged from the ink jet head onto an ITO (Indium Tin Oxide) electrode to achieve RGB separate application, prevents loss of the organic material and can improve the organic material utilization efficiency. This method is thus also effective.

However, separate application by deposition using a mask as proposed by Japanese Patent No. 2734464 and JP-A-8-227276 has problems in terms of mass production. For example, close adhesion to a large mask is difficult, and further, removal of organic substances accumulated on the mask is required.

In addition, techniques proposed by JP-A-3-105894, JP-A-6-13184, and JP-A-10-69981 have the following problems (1) to (4).

(1) Because a so-called light-emitting functional material is added to a matrix material, the light-emitting functional material content is low, and excellent light-emission properties cannot be achieved. (2) Due to the presence of optical absorption of the matrix material to be added, excellent light-emission characteristics cannot be achieved. (3) Because the light-emitting functional material is merely contained in the matrix material, the light-emitting functional material flows out during the development step after light irradiation, and thus excellent light-emission characteristics cannot be achieved. (4) In the case of using a heat-curable resin, by a usual method, it is difficult to prevent it from spreading around, and the reduction of a heated region is difficult. Further, downsizing requires the preparation of a special apparatus or the like, which is expensive, and the realizability thereof is poor.

In separate application using the ink jet method, in the case of forming RGB by ink jet printing, it is necessary to form a bank structure, which is called bank, and then drop ink thereto by ink jet printing. Further, surface treatment is required in order to make the ITO electrode surface hydrophilic and the bank hydrophobic.

As can be seen, for the problems in characteristics or due to the complicated processes, the conventional separate application techniques are hardly practical.

Therefore, it is desirable to provide a method for producing a display device, capable of achieving high light-emission efficiency and excellent video characteristics in a simple way; a composition for producing a display device; and a display device.

### SUMMARY

For achieving the above object, a first invention is a method for producing a display device including a first electrode, a second electrode, and at least one organic layer that is provided between the first electrode and second electrode and at least has a light-emitting layer. The method for producing a display device is characterized in that the light-emitting layer is formed through steps of: forming a composition layer including a radical initiator and a light-emitting material having radical-polymerization reactivity; exciting the composition layer to form in the composition layer a polymerized region where the composition layer is polymerized; and removing the composition layer except in the polymerized region.

According to a first embodiment, a display device having high light-emission efficiency and excellent video characteristics can be obtained in a simple way by forming the light-emitting layer thereof through steps of: forming a composition layer including a radical initiator and a light-emitting material having radical-polymerization reactivity; exciting the composition layer to form in the composition layer a polymerized region where the composition layer is polymerized; and removing the composition layer except in the polymerized region.

A second embodiment is a method for producing a display device including a first electrode, a second electrode, and at least one organic layer that is provided between the first electrode and second electrode and at least has a light-emitting layer. The method for producing a display device is characterized in that the light-emitting layer is formed through steps of: forming a composition layer including an acid generator and a light-emitting material that is polymerized; exciting the composition layer to form in the composition layer a depolymerized region where the light-emitting material is depolymerized; and removing the depolymerized region.

According to the second embodiment, a display device having high light-emission efficiency and excellent video characteristics can be obtained in a simple way by forming the light-emitting layer thereof through steps of: forming a composition layer including an acid generator and a light-emitting material that is polymerized; exciting the composition layer to form in the composition layer a depolymerized region where the light-emitting material is depolymerized; and removing the depolymerized region.

A third embodiment is a composition for producing a display device, the composition including a radical initiator and a light-emitting material having radical-polymerization reactivity.

According to the third embodiment, a display device having high light-emission efficiency and excellent video characteristics can be obtained in a simple way by forming the light-emitting layer thereof using a composition including a radical initiator and a light-emitting material having radical-polymerization reactivity.

A fourth embodiment is a composition for producing a display device, the composition including an acidolytic agent and a light-emitting material having radical-polymerization reactivity.

According to the fourth embodiment, a display device having high light-emission efficiency and excellent video characteristics can be obtained in a simple way by forming the light-emitting layer thereof using a composition including an acidolytic agent and a light-emitting material having radical-polymerization reactivity.

A fifth embodiment is a display device including a first electrode, a second electrode, and at least one organic layer that is provided between the first electrode and the second electrode and at least has a light-emitting layer, characterized in that the light-emitting layer includes a polymer compound with a structure containing a repeating unit derived from a light-emitting material having radical-polymerization reactivity.

According to the fifth embodiment, high light-emission efficiency and excellent video characteristics can be achieved.

Additional features and advantages are described herein, and will be apparent from, the following Detailed Description and the figures.

### BRIEF DESCRIPTION OF THE FIGURES

FIG. 1 is a sectional view showing an example of the configuration of a display device according to one embodiment.

FIG. 2A to FIG. 2F show a flow chart for explaining a first example of a method for producing a display device according to one embodiment.

FIG. 3G to FIG. 3L show a flow chart for explaining the first example of a method for producing a display device according to one embodiment.

FIG. 4A to FIG. 4F show a flow chart for explaining a second example of a method for producing a display device according to one embodiment.

FIG. 5G to FIG. 5L show a flow chart for explaining the second example of a method for producing a display device according to one embodiment.

FIG. 6A to FIG. 6F show a flow chart for explaining Example 1.

FIG. 7G to FIG. 7H show a flow chart for explaining Example 1.

FIG. 8A to FIG. 8F show a flow chart for explaining Example 2.

FIG. 9G to FIG. 9H show a flow chart for explaining Example 2.

FIG. 10A to FIG. 10F show a flow chart for explaining Example 3.

FIG. 11G to FIG. 11H show a flow chart for explaining Example 3.

FIG. 12A to FIG. 12F show a flow chart for explaining Example 4.

FIG. 13G to FIG. 13H show a flow chart for explaining Example 4.

FIG. 14A to FIG. 14F show a flow chart for explaining Example 5.

FIG. 15G to FIG. 15H show a flow chart for explaining Example 5.

### DETAILED DESCRIPTION

Certain embodiments will be explained hereinafter with reference to the drawings.

<Configuration of Display Device>

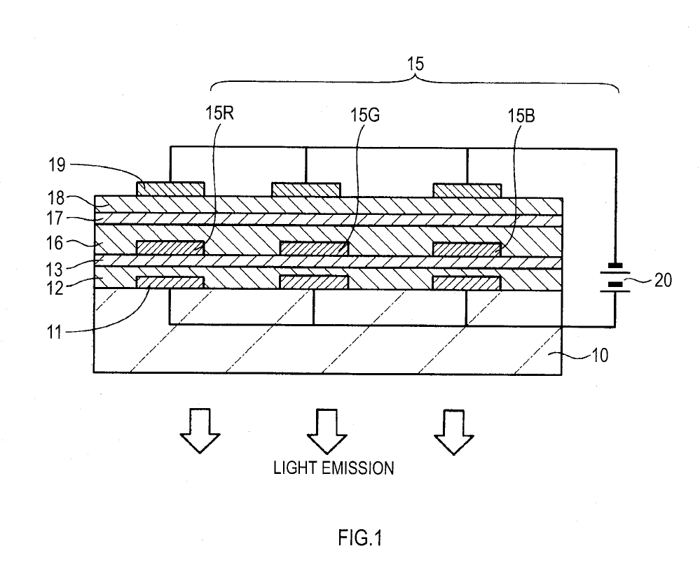

FIG. 1 is a sectional view showing an example of the configuration of a display device according to one embodiment.

The display device is a so-called bottom emission type, where emitted light is removed from the substrate-10 side. The display device includes, between a first electrode 11 disposed on the substrate 10 and a second electrode 19, the following layers in the following order, from the first-electrode-11 side: a hole injection layer 12, a hole transport layer 13, a light-emitting layer 15, a hole blocking layer 16, an electron transport layer 17, and an electron injection layer 18.

The substrate 10 is a transparent substrate that has no absorption in the visible region, and may be, for example, a soda lime substrate or like glass substrate, a plastic substrate, or the like.

The first electrode (anode) 11 is a transparent electrode that has no absorption in the visible region and has high electrical conductivity. The first electrode 11 is an electrode for injecting holes into the light-emitting layer 15. As required, the first electrode 11 is patterned to allow voltage-current to be applied to a predetermined position. The material for the first electrode 11 may be ITO, IZO (Indium Zinc Oxide), or a like oxide, for example.

The hole injection layer 12 and the electron injection layer 18 are provided to smoothly accept electrons and holes from the first electrode 11 and the second electrode 19. The hole transport layer 13 and the electron transport layer 17 are provided to smoothly transport electrons and holes to the light-emitting layer 15. The hole blocking layer 16 is provided to inhibit the entry of holes that degrade light-emission characteristics. For the hole injection layer 12, the hole transport layer 13, the hole blocking layer 16, and the electron transport layer 17, materials suitable for their functions may be used, respectively.

The light-emitting layer 15 includes a polymer compound with a structure containing a repeating unit derived from a light-emitting material having radical-polymerization reactivity. A plurality of layers are provided in order to achieve color light emission, including a red-light-emitting layer 15R that emits red light, a green-light-emitting layer 15G that emits green light, and a blue-light-emitting layer 15B that emits blue light. The red-light-emitting layer 15R, the green-light-emitting layer 15G, and the blue-light-emitting layer 15B are each formed from a suitable material.

The second electrode (cathode) 19 is an electrode for injecting electrons into the light-emitting layer 15. The second electrode 19 is electrically connected to the wire of the substrate 10. The material for the second electrode 19 may be, for example, aluminum (Al), a MgAg alloy, or the like.

In the display device, by applying required voltage-current between the first electrode 11 and the second electrode 19 via a power supply 20, holes and electrons are injected from the first electrode 11 and the second electrode 19, respectively, into the light-emitting layer 15. As a result of the recombination of the holes and the electrons in the light-emitting layer 15, light is emitted.

The display device has the following structure: first electrode 11/hole injection layer 12/hole transport layer 13/light-emitting layer 15/hole blocking layer 16/electron transport layer 17/electron injection layer 18/second electrode 19. However, the structure of the display device is not limited thereto. For example, the display device structure may also be, for example, first electrode 11/light-emitting layer 15/second electrode 19; first electrode 11/hole transport layer 13/light-emitting layer 15/electron transport layer 17/second electrode 19; or the like.

<First Example of Method for Producing Display Device>

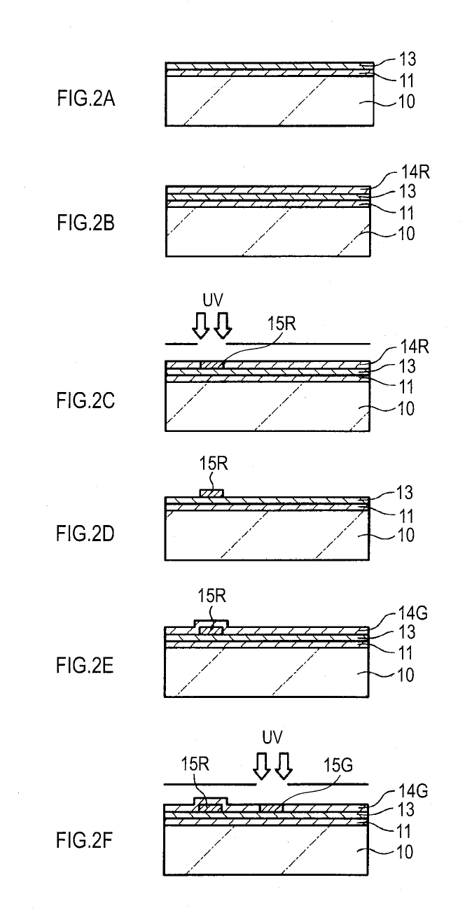

Next, the first example of a method for producing a display device will be explained with reference to FIG. 2 to FIG. 5. In the explanation of the first example of a method for producing a display device, an explanation will be given to the case of producing a display device with the following structure: first electrode 11/hole transport layer 13/light-emitting layer 15/electron transport layer 17/electron injection layer 18/second electrode 19. The elements common to FIG. 1 are indicated by the same reference numerals, and a detailed explanation will be omitted.

<Patterning of Red-Light-Emitting Layer 15R>

As shown in FIG. 2A, a first electrode 11 and a hole transport layer 13 are formed in this order on a substrate 10. If necessary, the first electrode 11 may have been patterned with an inorganic acid, such as hydrogen chloride, using a mask formed by photolithography or the like. The first electrode 11 and the hole transport layer 13 are formed by vacuum deposition, for example. When a material having polymerization reactivity is used for the hole transport layer 13, and electrons are emitted from hot filaments during the film formation to thereby promote the polymerization reaction, solvent resistance can be ensured at the time of development in a later step; this thus is preferable. When such a method in which electrons are emitted from hot filaments during the film formation to thereby promote the polymerization reaction is not employed in the formation of the hole transport layer 13, it is also possible to irradiate the entire surface with electrons after the film formation, thereby promoting the crosslinking reaction to polymerize the hole transport layer 13.

Further, as shown in FIG. 2B, a precursor layer 14R that serves as a precursor of a red-light-emitting layer 15R is formed on the hole transport layer 13 by vacuum deposition, for example. The precursor layer 14R is formed of a composition of a radical initiator and a light-emitting material having radical-polymerization reactivity.

As shown in FIG. 2C, at the time of UV irradiation, a mask is used so as to decompose the polymerization initiator to generate free radicals in a desired region of the precursor layer 14R. In the UV-irradiated region of the precursor layer 14R, the radical initiator is excited by UV irradiation to generate free radicals. With the generated free radicals, the light-emitting material undergoes a radical polymerization reaction and is thus polymerized. In terms of the stability of the radical initiator, UV irradiation is performed in a nitrogen gas or like inert gas atmosphere or in a vacuum atmosphere. Electron beam irradiation, ion irradiation, or X-ray irradiation may also be employed in stead of UV irradiation.

In this way, at the time of UV irradiation of the precursor layer 14R, by allowing a radical polymerization reaction to proceed only in a region exposed to UV irradiation using a mask, followed by development with chemicals in a later step, a red-light-emitting layer 15R can be formed in a desired region.

The light-emitting material having radical-polymerization reactivity includes, for example: a host material including an organic material that allows hole-electron recombination and has a radically reactive functional group introduced thereinto; and a guest material consisting of an organic material that emits light when excited molecules are deactivated. The guest material works as follows, for example. The recombination of holes and electrons in the host material brings the host material into an excited state, and such excitation energy is transferred to the guest material, whereby the guest material is excited and thus emits light. Alternatively, for example, the guest material is excited by the recombination of electrons and holes in the host material, and thereby emits light.

Specifically, as the host material having a radical functional group introduced thereinto, a compound represented by Chemical Formula 1 may be used, for example. More specifically, a compound represented by Chemical Formula 2 may be used. Further, more specifically, a compound represented by Chemical Formula 3 may be used.

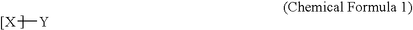

In the formula, X is an organic compound that allows hole-electron recombination, and Y is a radically reactive functional group, such as a vinyl group, an acrylic acid group, or a methacrylic acid group, introduced into any moiety of X.

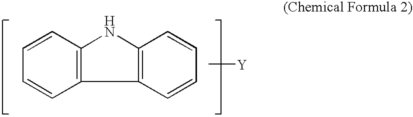

In the formula, Y is a radically reactive functional group, such as a vinyl group, an acrylic acid group, or a methacrylic acid group, introduced into any moiety of carbazole.

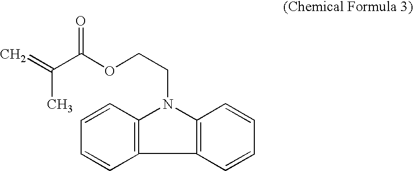

Because the host material has a radically reactive functional group, only a UV-irradiated region thereof can be polymerized. In order to obtain improved light-emission efficiency, the number of radically reactive functional groups contained is preferably one.

Further, in the case where a material containing a radically reactive functional group is used as the guest material, because such a material forms a copolymer with the host material, this reduces the elution of the guest material at the time of removing a non-polymerized region in a later step. Such a use is thus preferable.

Further, in the case where a fluorescent material is used as the guest material, as compared with a phosphorescent material, material synthesis is easier, the impurity content that leads to deterioration of characteristics is lower, and a high-purity material can be more easily obtained. In addition, unlike phosphorescent materials, fluorescent materials are synthesized without using iridium, platinum, or a like expensive material, and thus are less expensive than phosphorescent materials. Further, unlike phosphorescent materials, fluorescent materials do not have a complex structure but have a stable molecular structure, and thus are thermally stable.

As shown in FIG. 2D, a non-polymerized region is removed to form a patterned red-light-emitting layer 15R. The non-polymerized region can be selectively removed by dissolution using an organic solvent or by heating the substrate. Removal by heating is preferable for reducing the degradation of materials.

<Patterning of Green-Light-Emitting Layer 15G>

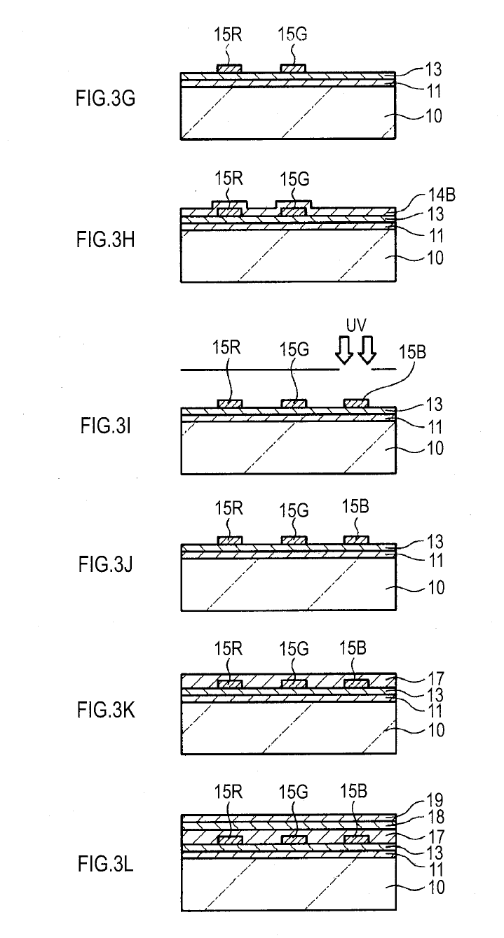

As shown in FIG. 2E to FIG. 2F and FIG. 3G, a precursor layer 14G of a green-light-emitting layer 15G is formed on the hole transport layer 13 and the patterned red-light-emitting layer 15R, and then the steps shown in FIG. 2C to FIG. 2D are successively performed to form a patterned green-light-emitting layer 15G.

<Patterning of Blue-Light-Emitting Layer 15G>

As shown in FIG. 3H to FIG. 3J, a precursor layer 14B of a blue-light-emitting layer 15B is formed on the hole transport layer 13, the patterned red-light-emitting layer 15R, and the patterned green-light-emitting layer 15G, and then the steps shown in FIG. 2C to FIG. 2D are successively performed to form a patterned blue-light-emitting layer 15B.

<Formation of Electron Transport Layer 17, Electron Injection Layer 18, and Second Electrode 19>

As shown in FIG. 3K to FIG. 3L, an electron transport layer 17, an electron injection layer 18, and a second electrode 19 are formed in this order by vacuum deposition, for example, on the first electrode 11 and the light-emitting layers 15R to 15B. A display device is thus completed.

In the first example of a method for producing a display device shown in FIG. 2 to FIG. 3, as specific materials, in addition to the materials mentioned above, the following materials may be suitably selected and used. As the light-emitting material, any of the below-mentioned materials may be used with a radically reactive functional group introduced thereinto.

As radical photopolymerization initiators, alkylphenone-based photopolymerization initiators are usable, examples thereof including 2,2-dimethoxy-1,2-diphenylethan-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methyl-propan-1-one, 2-methyl-1-(4-methylthiophenyl)-2-morpholinopropan-1-one, and 2-benzyl-2-dimethylamino-1-(4-morpholinophenyl)-butanone-1,2-(dimethylamino)-2-[(4-methylphenyl)methyl]-1-[4-(4-morpholinyl)phenyl]-1-butanone.

Acylphosphine-oxide-based photopolymerization initiators are also usable, examples thereof including 2,4,6-trimethylbenzoyl-diphenyl-phosphine oxide and bis(2,4,6-trimethylbenzoyl)-phenylphosphine oxide.

Titanocene-based photopolymerization initiators are also usable, examples thereof including bis(η5-2,4-cyclopentadien-1-yl)-bis(2,6-difluoro-3-(1H-pyrrol-1-yl)-phenyl)titanium.

As other photopolymerization initiators, oxime esters are usable, examples thereof including 1,2-octanedione, 1-[4-(phenylthio)-,2-(O-benzoyloxime)], and ethanone, 1-[9-ethyl-6-(2-methylbenzoyl)-9H-carbazole-3-yl]-,1-(0-acetyloxime).

Oxyphenylacetic acid esters are also usable, examples thereof including a mixture of oxyphenylacetic acid 2-[2-oxo2-phenylacetoxyethoxy]ethyl ester and oxyphenylacetic acid 2-(2-hydroxyethoxy)ethyl ester.

As polymerization promoters, ethyl-4-dimethylaminobenzoate, 2-ethylhexyl-4-dimethylaminobenzoate, and the like are usable, for example.

As cationic photopolymerization initiators, A: iodonium, (4-methylphenyl)[4-(2-methylpropyl)phenyl]-hexafluorophosphate(1-), B: propylene carbonate, and the like are usable.

As fluorescent dyes, fluorescent compounds such as coumarin dyes, pyran dyes, cyanine dyes, and croconium dyes are usable, for example.

Polycyclic aromatic hydrocarbons such as anthracenes, pyrenes, and perylenes are also usable, for example.

Further, heteroaromatic compounds are also usable, examples thereof including oxazol, thiazole, imidazole, oxadiazole, thiadiazole, lophine, coumarin, Nile red, 4H-pyranylidenepropanedinitrile derivatives, polythiophene, and polyvinyl carbazole.

Further, polymethine compounds are also usable, examples thereof including cyanine, oxonol, azulenium, and pyrylium.

Further, stilbene compounds are also usable, examples thereof including diaminostilbene derivatives, polyphenylene vinylene, azomethine, and azobenzene.

Further, chelate metal complexes are also usable, examples thereof including quinolines, naphthalenes, 8-quinolinol, Al3+ complexes, and beryllium complexes.

Further, zinc complexes are also usable, examples thereof including quinolinol, 2-hydroxyphenyl benzoxazole, 2-(2-pyridyl)phenol, 2-(3-oxadiazolyl)phenol derivatives, and 2-hydroxybenzylidene aniline derivatives (azomethine compounds).

Further, chelate lanthanoid complexes are also usable, examples thereof including B xanthene dyes such as fluoreselen and rhodamine.

Further, dyes related to organic pigments, such as quinacridone, diketopyrrolopyrrole derivatives, and copper phthalocyanine, are also usable, for example. Inorganic/organic complex systems, polysilane, spiro compounds, squarylium dyes, fluorescein, and the like are also usable.

As phosphorescent dyes, the following green materials, blue materials, red materials, and the like are usable.

As green materials, tris(2-phenylpyridine)iridium(III) (Ir(ppy)3), bis(2-phenylpyridine)(acetylacetonate)iridium(II), tris[2-(p-tolyl)pyridine]iridium(III) (Ir(mppy)3), and the like are usable.

As blue materials, bis(3,5-difluoro-2-(2-pyridyl)phenyl)-(2-carboxypyridyl)iridium(III) (FirPic), bis(48,68-difluorophenylpyridinato)tetrakis(1-pyrazolyl)borate iridium(III) (FIr6), and the like are usable.

As red materials, tris(1-phenylisoquinoline)iridium(III) (Ir(piq)3), bis(1-phenylisoquinoline)(acetylacetonate)iridium(III) (Ir(piq)2(acac)), bis[1-(9,9-dimethyl-9H-fluoren-2-yl)-isoquinoline](acetylacetonate)iridium(III) (Ir(fliq)2(acac)), bis[3-(9,9-dimethyl-9H-fluoren-2-yl)isoquinoline](acetylacetonate)iridium(III) (Ir(flq)2(acac)), tris(2-phenylquinoline)iridium(III) (Ir(2-phq)3), bis(2-phenylquinoline)(acetylacetonate)iridium(III) (Ir(2-phq)2(acac)), and the like are usable.

As hole transport materials, N,N′-bis(3-methylphenyl)-N,N′-diphenyl-[1,1′-biphenyl]-4,4′-diamine (TPD), 4,4′,4″-tris[3-methylphenyl(phenyl)amino]triphenylamine (m-MTDATA), 4,4′,4″-tris[1-naphthyl(phenyl)amino]triphenylamine (1-TNATA), 4,4′,4″-tris[2-naphthyl(phenyl)amino]triphenylamine (2-TNATA), 4,4′,4″-tris[biphenyl-4-yl(3-methylphenyl)amino]triphenylamine (p-PMTDATA), 4,4′,4″-tris[9,9-dimethyl-2-fluorenyl(phenyl)amino]triphenylamine (TFATA), 4,4′,4″-tri(N-carbazolyl)triphenylamine (TCTA), 1,3,5-tris[N-(4-diphenylaminophenyl)phenylamino]benzene (p-DPA-TDAB), 1,3,5-tris {4-[methylphenyl(phenyl)amino]phenyl}benzene (MTDAPB), N,N″-di(biphenyl-4-yl)-N,N′-diphenyl-[1,1′-biphenyl]-4,4′-diamine (p-BPD), N,N,N′,N′-tetrakis(9,9-dimethyl-2-fluorenyl)-[1,1′-biphenyl]-4,4′-diamine (FFD), and the like are usable.

As electron transport materials, Alq3(tris(8-quinolinolate)aluminum(III)), oxadiazole derivatives and the like, 1,3,5-tris[5-(4-tert-butylphenyl)-1,3,4-oxadizol-2-yl]benzene (TPOB), 5,5′-bis(dimesitylboryl)-2,2′-bithiophene (BMB-2T), 5,5′-bis(dimesitylboryl)-2,2′:5′,2″-terthiophene (BMB-3T), and the like are usable.

As luminescent amorphous molecular materials, tri(o-terphenyl-4-yl)amine (o-TTA), tri(p-terphenyl-4-yl)amine (p-TTA), and the like are usable. As oligothiophene derivatives, 2,5-bis{4-[bis(4-methylphenyl)amino]phenyl}triophene (BMA-1T), 5,5′-bis{4-[bis(4-methylphenyl)amino]phenyl}-2,2′-bithiophene (BMA-2T), 5,5′-bis{4-[bis(4-methylphenyl)amino]phenyl}-2,2′:5′,2″-terthiophene (BMA-3T), 5,5″″-bis{4-[bis(4-methylphenyl)amino]phenyl}-2,2′:5′2″:5″,2′″-quaterthiophene (BMA-4T), and the like are usable.

In the first example of a method for producing a display device, in the case of multicolor separate application, the hole transport layer 13 is formed on the first electrode 11 that is a transparent electrode, and then the precursor layer 14R of the red-light-emitting layer 15R, the first color, is formed over the entire surface thereof. Subsequently, UV light is applied thereto to promote the polymerization reaction in a desired region, followed by development, thereby forming the patterned red-light-emitting layer 15R.

Subsequently, on the red-light-emitting layer 15R of the first color, the precursor layer 14G of the green-light-emitting layer 15G, the second color, is formed over the entire surface. Subsequently, a desired position is exposed to UV irradiation to promote the polymerization reaction of the precursor layer 14G of the second color, whereby solvent insolubilization in the irradiated region can be achieved. The same procedure is repeated to form the blue-light-emitting layer 15B, the third color. After patterning is thus completed for the so-called RGB three colors, the electron transport layer 17, the electron injection layer 18, and the second electrode 19 are formed. As a result, removal is possible without damaging a light-emitting layer 15 and like organic layers, whereby an organic light-emitting diode having improved light-emission characteristics can be formed. Therefore, a flat panel display device can be reliably formed in a simple way, making it possible to form an organic light-emitting diode having improved characteristics.

<Second Example of Method for Producing Display Device>

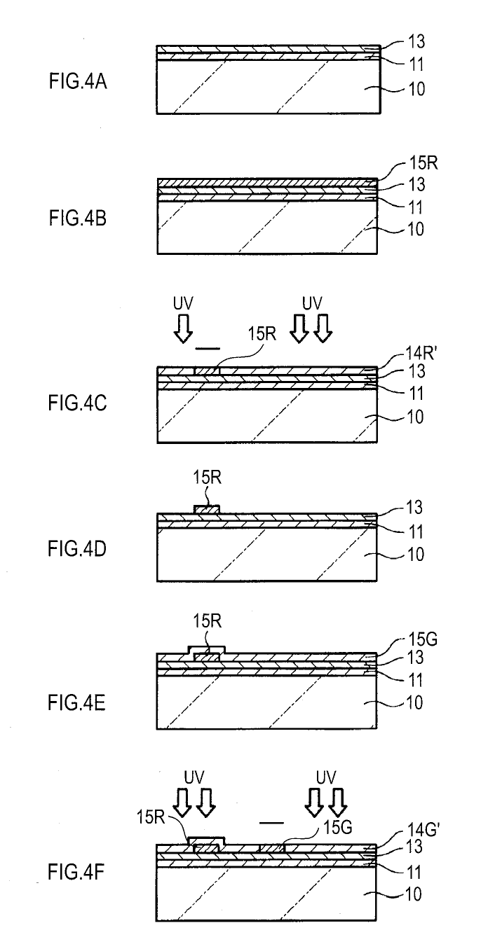

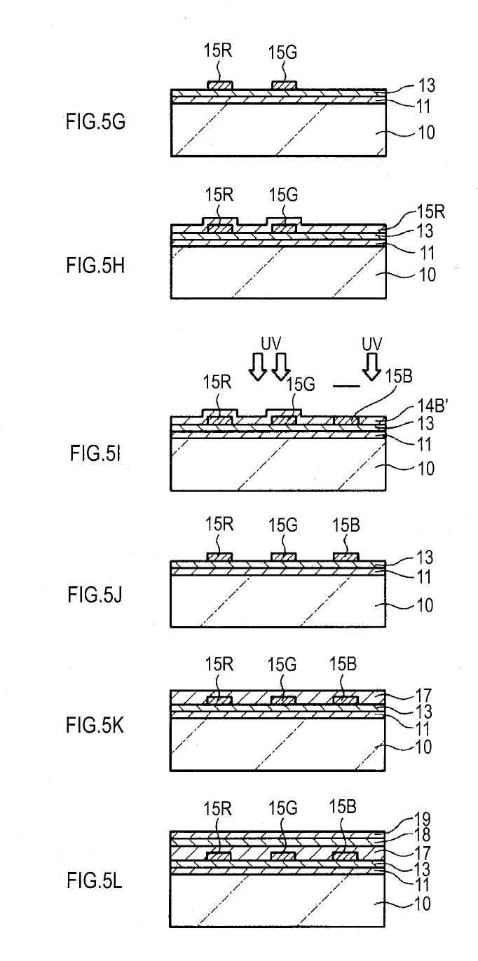

The second example of a method for producing a display device will be explained with reference to FIG. 4 to FIG. 5. In the explanation of the second example of a method for producing a display device, an explanation will be given to the case of producing a display device with the following structure: first electrode 11/hole transport layer 13/light-emitting layer 14/electron transport layer 17/electron injection layer 18/second electrode 19. The elements common to FIG. 1 are indicated by the same reference numerals, and a detailed explanation will be omitted.

<Patterning of Red-Light-Emitting Layer 15R>

As shown in FIG. 4, a first electrode 11 and a hole transport layer 13 are formed in this order on a substrate 10. If necessary, the first electrode 11 may have been patterned with an inorganic acid, such as hydrogen chloride, using a mask formed by photolithography or the like. The first electrode 11 and the hole transport layer 13 are formed by vacuum deposition, for example. When a material having polymerization reactivity is used for the hole transport layer 13, and electrons are emitted from hot filaments during the film formation to thereby promote the polymerization reaction, solvent resistance can be ensured at the time of development in a later step; this thus is preferable. When such a method in which electrons are emitted from hot filaments during the film formation to thereby promote the polymerization reaction is not employed in the formation of the hole transport layer 13, it is also possible to irradiate the entire surface with electrons after the film formation, thereby promoting the crosslinking reaction to polymerize the hole transport layer 13.

Further, as shown in FIG. 4B, a composition including an acid generator and a light-emitting material having radical-polymerization reactivity is formed on the hole transport layer 13 by vacuum deposition or the like, followed by irradiation with an electron beam or the like to polymerize the light-emitting material, thereby forming a red-light-emitting layer 15R. The light-emitting material may also be polymerized, for example, by heating under a vacuum of 1e-5 torr at 150° C. for 1 hour, for example.

As shown in FIG. 4C, at the time of UV irradiation, a mask is used so that an acid is generated from the acid generator in a desired region of the red-light-emitting layer 15R. In the UV-irradiated region, the acid generator contained in the red-light-emitting layer 15R generates an acid, and the generated acid reacts with the polymerized light-emitting material to cause main chain scission, thereby forming a depolymerized region (referred a photolysis region 14R′).

As shown in FIG. 4D, the photolysis region 14R′ is removed by dissolution with an organic solvent to form a patterned red-light-emitting layer 15R. The photolysis region 14R′ may also be removed by heating. Removal by heating is preferable for reducing the degradation of materials.

<Patterning of Green-Light-Emitting Layer 15G>

As shown in FIG. 4E to FIG. 4F and FIG. 5G, a composition including an acid generator and a light-emitting material having radical-polymerization reactivity is formed on the hole transport layer 13 and the patterned red-light-emitting layer 15R, and irradiation with an electron beam or the like is then performed to polymerize the light-emitting material, thereby forming a green-light-emitting layer 15G. Then, the steps shown in FIG. 4C to FIG. 4D are successively performed to remove a photolysis region 14G′, thereby forming a patterned green-light-emitting layer 15G.

<Patterning Blue-Light-Emitting Layer 15B>

As shown in FIG. 5H to FIG. 5J, a composition including an acid generator and a light-emitting material having radical-polymerization reactivity is formed on the hole transport layer 13, the patterned red-light-emitting layer 15R, and the patterned green-light-emitting layer 15G, and irradiation with an electron beam or the like is then performed to polymerize the light-emitting material, thereby forming a blue-light-emitting layer 15B. Then, the steps shown in FIG. 4C to FIG. 4D are successively performed to remove a photolysis region 14B′, thereby forming a patterned blue-light-emitting layer 15B.

<Formation of Electron Transport Layer 17, Electron Injection Layer 18, and Second Electrode 19>

As shown in FIG. 5K to FIG. 5L, an electron transport layer 17, an electron injection layer 18, and a second electrode 19 are formed in this order by vacuum deposition, for example, on the first electrode 11 and the light-emitting layers 15R to 15B. A display device is thus completed.

In the second example of a method for producing a display device, an aromatic diazonium salt, o-quinonediazide, o-naphthoquinonediazide sulfonic acid chloride, or the like can be used as the acid generator. In addition, the same materials as those described in the first example of a method for producing a display device may also be suitably selected and used.

In the second example of a method for producing a display device, in the case of multicolor separate application, the hole transport layer 13 is formed on the first electrode 11 that is a transparent electrode, and then the red-light-emitting layer 15R, the first color, is formed over the entire surface thereof. Subsequently, UV light is applied thereto to promote the acidolysis reaction in a desired region, followed by development, thereby forming the patterned red-light-emitting layer 15R.

Subsequently, on the red-light-emitting layer 15R of the first color, the green-light-emitting layer 15G, the second color, is formed over the entire surface. UV light is then applied to a desired position to promote the acidolysis reaction of the green-light-emitting layer 15G of the second color, whereby solvent solubilization in the irradiated region can be achieved. The same procedure is repeated to form the blue-light-emitting layer 15B, the third color. After patterning is thus completed for the so-called RGB three colors, the electron transport layer 17, the electron injection layer 18, and the second electrode 19 are formed. As a result, removal is possible without damaging a light-emitting layer 15 and like organic layers, and an organic light-emitting diode having improved light-emission characteristics can be formed. Therefore, a flat panel display device can be reliably formed in a simple way, making it possible to form an organic light-emitting diode having improved characteristics.

Specific examples of the invention will be explained with reference to the drawings. However, the invention is not limited to these examples.

### Example 1

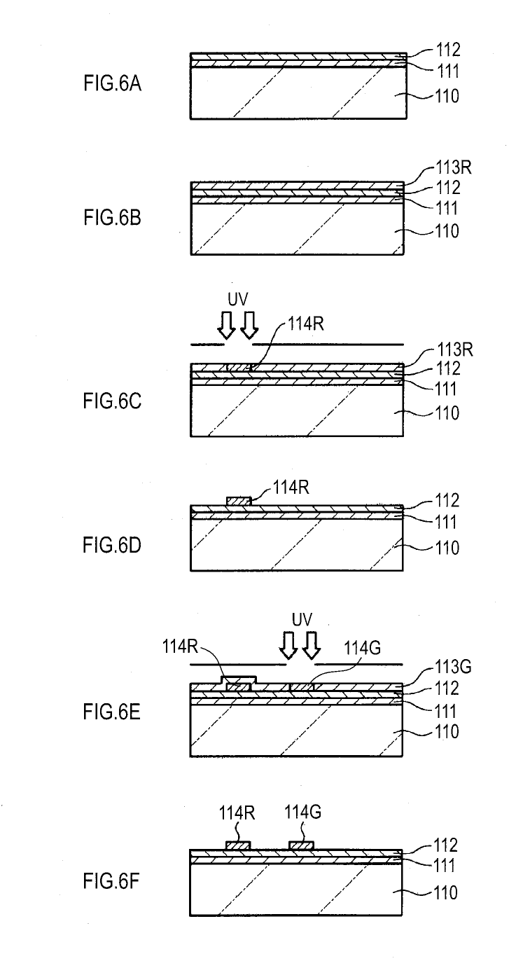

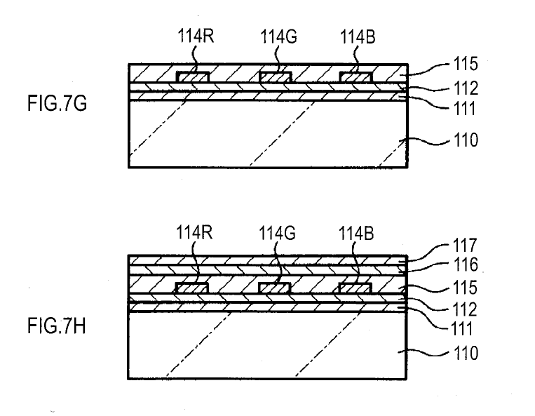

Example 1 is particularly a specific example where a display device was produced using acrylcarbazole having radical-polymerization reactivity as the host material of a light-emitting material, an Ir dye as the guest material thereof, and benzophenone as a radical initiator. Hereinafter, Example 1 will be explained with reference to FIG. 6 to FIG. 7.

As shown in FIG. 6, on a soda lime glass substrate 110, an ITO layer 111 with a thickness of 100 nm was formed by normal sputtering as a conductive layer having no absorption in the visible region for application of voltage-current. In Example 1, the ITO layer 111 was not patterned.

Further, a hole transport layer 112 was formed under the following conditions. In order to ensure solvent resistance at the time of development in a later step, electrons were emitted from hot filaments during the film production to thereby promote the polymerization reaction.

(Conditions for Forming Hole Transport Layer 112)
Raw material: Acrylic-modified N,N′-bis(3-methylphenyl)-N,N′-diphenyl-[1,1′-biphenyl]-4,4′-diamine (acryl-TPD)
Deposition condition: Deposition temperature/deposition pressure=200° C./1e-5 torr

As shown in FIG. 6B, after forming the hole transport layer 112, a precursor layer 113R to serve as a precursor of a red-light-emitting layer 114R was formed by vacuum deposition under the following conditions. Benzophenone employed as a radical initiator, which causes a polymerization reaction in response to UV irradiation in a later step, was deposited together with the host material and the guest material.

(Conditions for Forming Precursor Layer 113R)
Raw material: Host material: Carbazole acrylate
Guest material: Tris(1-phenylisoquinoline)iridium(III)
Initiator material: Benzophenone
Deposition condition: Deposition temperature/deposition pressure=200° C./1e-5 torr

As shown in FIG. 6C, after forming the precursor layer 113R, a desired region of the precursor layer 113R was exposed to UV irradiation 113R using a mask so as to decompose the radical initiator to generate free radicals. The UV-irradiated region of the precursor layer 113R undergoes a radical polymerization reaction and is thus polymerized.

As shown in FIG. 6D, a non-polymerized region was removed by dissolution with an organic solvent to form a patterned red-light-emitting layer 114R.

As shown in FIG. 6E, a precursor layer 113G to serve as a precursor of a green-light-emitting layer 114G was formed under the following conditions. Benzophenone employed as a radical initiator was deposited together with the host material and the guest material.

(Conditions for Forming Precursor Layer 113G)
Raw material: Host material: Carbazole acrylate
Guest material: Tris(2-phenylpyridine)iridium(III)
Initiator material: Benzophenone
Deposition condition: Deposition temperature/deposition pressure=200° C./1e-5 torr

After forming the precursor layer 113G, a desired region of the precursor layer 113R was exposed to UV irradiation 113G using a mask so as to decompose the radical initiator contained in the precursor layer 113G to generate free radicals.

Further, as shown in FIG. 6F, a non-polymerized region was removed by dissolution with an organic solvent to form a patterned red-light-emitting layer 114G.

As shown in FIG. 7G, a precursor layer to serve as a precursor of a blue-light-emitting layer 114B was further formed on the hole transport layer 112, the red-light-emitting layer 114R, and the green-light-emitting layer 114G under the following conditions, and then the same steps as shown in FIG. 6C to FIG. 6D were successively performed. An electron transport layer 115 was then formed in a desired region under the following conditions.

(Conditions for Forming Precursor Layer of Blue-Light-Emitting Layer 114B)
Raw material: Host material: Carbazole acrylate
Guest material: Bis(3,5-difluoro-2-(2-pyridyl)phenyl-(2-carboxypyridyl)iridium(III)
Initiator material: Benzophenone
Deposition condition: Deposition temperature/deposition pressure=180° C./1e-5 torr

(Conditions for Forming Electron Transport Layer 115)
Raw material: Quinolinol aluminum complex: (tris(8-quinolinolate)aluminum(III) (Alq3)
Deposition condition: Deposition temperature/deposition pressure=200° C./1e-5 torr

Further, as shown in FIG. 7H, an electron injection layer 116 and an electrode layer 117 were formed in a desired region under the following conditions. A display device was thus completed.

(Conditions for Forming Electron Injection Layer)
Raw material: LiF
Deposition condition: Deposition temperature/deposition pressure=300° C./1e-5 torr

(Conditions for Forming Electrode Layer)
Raw material: Al
Deposition condition: Deposition temperature/deposition pressure=200° C./1e-5 torr

### Example 2

Example 2 is particularly a specific example where a display device was produced using acrylcarbazole having radical-polymerization reactivity as the host material of a light-emitting material, an Ir dye also having radical-polymerization reactivity as the guest material thereof, and methylaminobenzophenone as a radical initiator.

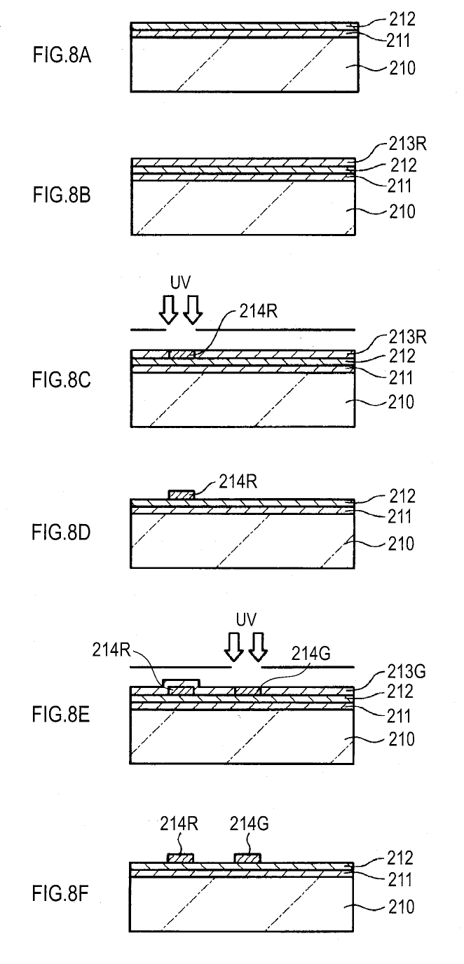

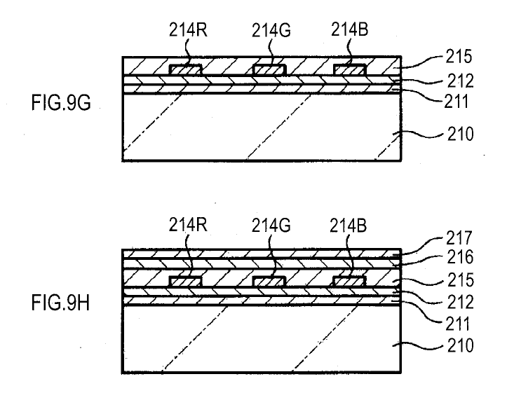

In Example 2, a guest material having radical-polymerization reactivity is used, and therefore free radicals are generated at the time of UV irradiation, whereby the guest material also undergoes a radical polymerization reaction or a copolymerization reaction with the host material. Supposedly, the guest material can thus be effectively prevented from dissolving and flowing out in a later step of removing a non-polymerized region with chemicals. Hereinafter, Example 2 will be explained with reference to FIG. 8 to FIG. 9.

As shown in FIG. 8, on a soda lime glass substrate 210, an ITO layer 211 with a thickness of 100 nm was formed by normal sputtering as a conductive layer having no absorption in the visible region for application of voltage-current. In Example 2, the ITO layer 211 was not patterned.

Further, a hole transport layer 212 was formed under the following conditions. In order to ensure solvent resistance at the time of development in a later step, electrons were emitted from hot filaments during the film production to thereby promote the polymerization reaction.

(Conditions for Forming Hole Transport Layer 212)
Raw material: N,N′-bis(3-methylphenyl)-N,N′-diphenyl-[1,1′-biphenyl]-4,4′-diamine, acrylic-modified (acryl-TPD)
Deposition condition: Deposition temperature/deposition pressure=200° C./1e-5 torr

As shown in FIG. 8B, after forming the hole transport layer 212, a precursor layer 213R to serve as a precursor of a red-light-emitting layer 214R was formed by vacuum deposition under the following conditions. Methylaminobenzophenone employed as a radical initiator was deposited together with the host material and the guest material.

(Conditions for Forming Precursor Layer 213R)
Raw material: Host material: Carbazole acrylate
Guest material: Acrylic-modified bis(1-phenylisoquinoline)(acetylacetonate)iridium(III)
Initiator material: Methylaminobenzophenone
Deposition condition: Deposition temperature/deposition pressure=200° C./1e-5 torr

After the film formation, as shown in FIG. 8G, after forming the precursor layer 213R, a desired region of the precursor layer 213R was exposed to UV irradiation using a mask so as to decompose the radical initiator contained in the precursor layer 213R to generate free radicals. The UV-irradiated region undergoes a radical polymerization reaction and is thus polymerized.

Further, as shown in FIG. 8D, a non-polymerized region was removed by dissolution with an organic solvent to form a patterned red-light-emitting layer 214R.

As shown in FIG. 8E, a precursor layer 213G to serve as a precursor of a green-light-emitting layer 214G was formed under the following conditions. Methylaminobenzophenone employed as a radical reaction initiator was deposited together with the host material and the guest material.

(Conditions for Forming Precursor Layer 213G)
Raw material: Host material: Carbazole acrylate
Guest material: Acrylic-modified bis(2-phenylpyridine)(4-vinylphenylpyridine)iridium(III)
Initiator material: Methylaminobenzophenone
Deposition condition: Deposition temperature/deposition pressure=200° C./1e-5 torr

After forming the precursor layer 213G, a desired region of the precursor layer 213G was exposed to UV irradiation using a mask so as to decompose the radical initiator contained in the precursor layer 213G to generate free radicals.

Further, as shown in FIG. 8F, a non-polymerized region was removed by dissolution with an organic solvent to form a patterned green-light-emitting layer 214G.

As shown in FIG. 9G, a precursor layer to serve as a precursor of a blue-light-emitting layer 214B was further formed on the hole transport layer 212, the red-light-emitting layer 214R, and the green-light-emitting layer 214G under the following conditions, and then the same steps as shown in FIG. 8C to FIG. 8D were successively performed to form a patterned blue-light-emitting layer 214B. Subsequently, an electron transport layer 215 was further formed in a desired region under the following conditions.

(Conditions for Forming Precursor Layer of Blue Light Emission 214B)
Raw material: Host material: Carbazole acrylate
Guest material: Bis(48,68-difluorophenylpyridinato)tetrakis(1-pyrazolyl)borate iridium(III) (FIr6)
Initiator material: Benzophenone
Deposition condition: Deposition temperature/deposition pressure=180° C./1e-5 torr

(Conditions for Forming Electron Transport Layer 215)
Raw material: Quinolinol aluminum complex; (tris(8-quinolinolate)aluminum (Alq3)
Deposition condition: Deposition temperature/deposition pressure=200° C./1e-5 torr

Further, as shown in FIG. 9H, an electron injection layer 216 and an electrode layer 217 to serve as the upper electrode were formed in a desired region under the following conditions. A display device was thus completed.

(Conditions for Forming Electron Injection Layer 216)
Raw material: LiF
Deposition condition: Deposition temperature/deposition pressure=300° C./1e-5 torr

(Conditions for Forming Electrode Layer 217)
Raw material: Al
Deposition condition: Deposition temperature/deposition pressure=200° C./1e-5 torr

### Example 3

Example 3 is particularly a specific example where acrylcarbazole having radical-polymerization reactivity was used as the host material of a light-emitting material, an Ir dye also having radical-polymerization reactivity as the guest material thereof, and dimethylaminobenzophenone as a radical initiator.

In Example 3, a guest material having radical-polymerization reactivity is used, and therefore free radicals are generated at the time of UV irradiation, whereby the guest material also undergoes a radical polymerization reaction or a copolymerization reaction with the host material. Supposedly, the guest material can thus be effectively prevented from dissolving and flowing out in a later step of removing a non-polymerized region.

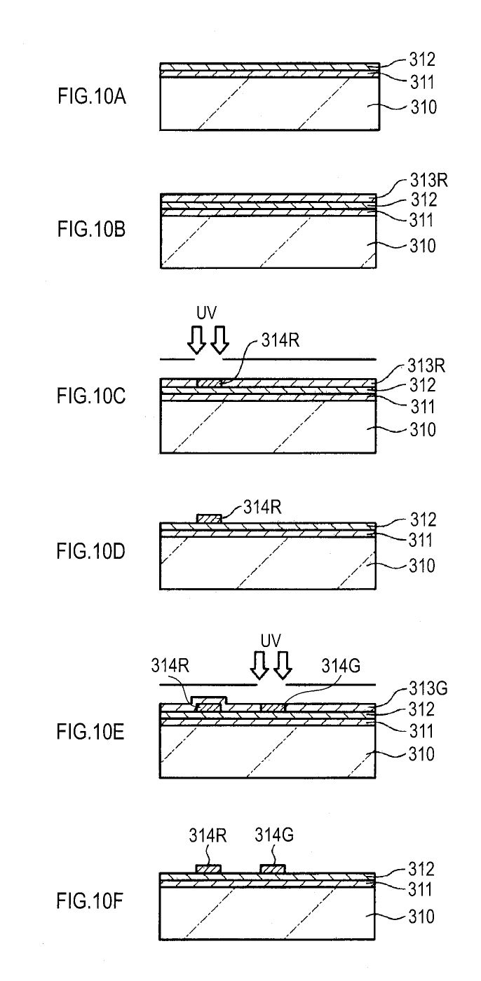

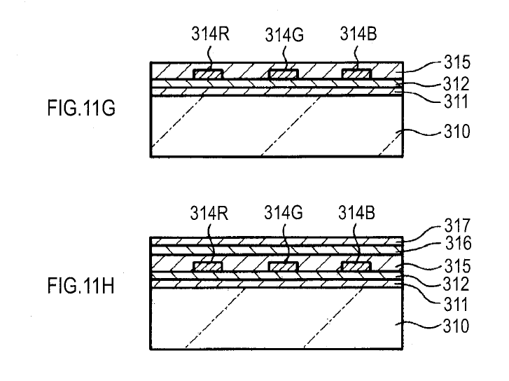

Example 3 is also a specific example where the non-polymerized region was removed by heating so as to minimize damages on each light-emitting layer in contrast to Example 2 where chemicals were used in the non-polymerized region removal step. Hereinafter, Example 3 will be explained with reference to FIG. 10 to FIG. 11.

As shown in FIG. 10, on a soda lime glass substrate 310, an ITO layer 311 with a thickness of 100 nm was formed by normal sputtering as a conductive layer having no absorption in the visible region for application of voltage-current. In Example 3, the ITO layer 311 was not patterned.

Further, a hole transport layer 312 was formed under the following conditions. In order to ensure solvent resistance at the time of development in a later step, electrons were emitted from hot filaments during the film production to thereby promote the polymerization reaction.

<Conditions for Forming Hole Transport Layer 312>
Raw material: N,N′-bis(3-methylphenyl)-N,N′-diphenyl-[1,1′-biphenyl]-4,4′-diamine, acrylic-modified (acryl-TPD)
Deposition condition: Deposition temperature/deposition pressure=200° C./1e-5 torr

As shown in FIG. 10B, after forming the hole transport layer 312, a precursor layer 313R to serve as a precursor of a red-light-emitting layer 314R was formed by vacuum deposition under the following conditions. Methylaminobenzophenone employed as a radical initiator, which causes a polymerization reaction in response to UV irradiation in a later step, was deposited together with the host material and the guest material.

<Conditions for Forming Precursor Layer 314R>
Raw material: Host material: Carbazole acrylate
Guest material: Acrylic-modified bis(1-phenylisoquinoline)(acetylacetonate)iridium(III)
Initiator material: Methylaminobenzophenone
Deposition condition: Deposition temperature/deposition pressure=200° C./1e-5 torr

As shown in FIG. 10C, after forming the precursor layer 313R, a desired region of the precursor layer 313R was exposed to UV irradiation using a mask in order to decompose the initiator contained in the precursor layer 313R to generate free radicals. The UV-irradiated region of the precursor layer 313R undergoes a radical polymerization reaction and is thus polymerized.

As shown in FIG. 10D, the substrate 310 was heated under the following conditions to remove a non-polymerized region, thereby forming a patterned red-light-emitting layer 314R.

(Heating Conditions)
Heating temperature/pressure=200° C./1e-5 torr

As shown in FIG. 10E, a precursor layer 313G to serve as a precursor of a green-light-emitting layer 314G was formed by vacuum deposition under the following conditions. Dimethylaminobenzophenone employed as a radical initiator was deposited together with the host material and the guest material.

(Conditions for Forming Precursor Layer 313G)
Raw material: Host material: Carbazole acrylate
Guest material: Acrylic-modified bis(2-phenylpyridine)(acetylacetonate)iridium(II)
Initiator material: Dimethylaminobenzophenone
Deposition condition: Deposition temperature/deposition pressure=200° C./1e-5 torr

After forming the precursor layer 313G, a desired region of the precursor layer 313G was exposed to UV irradiation using a mask so as to decompose the radical initiator contained in the precursor layer 313G to generate free radicals.

Further, as shown in FIG. 10F, the substrate 310 was heated under the following conditions to remove a non-polymerized region, thereby forming a patterned green-light-emitting layer 313G.

(Heat Condition)
Heating temperature/pressure=200° C./1e-5 torr

As shown in FIG. 11G, a precursor layer to serve as a precursor of a blue-light-emitting layer 314B was further formed on the hole transport layer 312, the red-light-emitting layer 314R, and the green-light-emitting layer 314G under the following conditions, and then the same steps as shown in FIG. 10C to FIG. 10D were successively performed to form a patterned blue-light-emitting layer 314B. Subsequently, an electron transport layer 315 was formed in a desired region under the following conditions.

(Conditions for Forming Precursor Layer of Blue-Light-Emitting Layer 314B)
Raw material: Host material: Carbazole acrylate
Guest material: Acrylic-acid-modified bis(48,68-difluorophenylpyridinato)tetrakis(1-pyrazolyl)borate iridium(III) (FIr6)
Initiator material: Dimethylaminobenzophenone
Deposition condition: Deposition temperature/deposition pressure=190° C./1e-5 torr

(Conditions for Forming Electron Transport Layer 315)
Raw material: Quinolinol aluminum complex: (tris(8-quinolinolate)aluminum(III) (Alq3)
Deposition condition: Deposition temperature/deposition pressure=200° C./1e-5 torr

Further, as shown in FIG. 11H, an electron injection layer 316 and an electrode layer 317 to serve as the upper electrode were formed in a desired region by vacuum deposition under the following conditions. A display device was thus completed.

(Conditions for Forming Electron Injection Layer 316)
Raw material: LiF
Deposition condition: Deposition temperature/deposition pressure=300° C./1e-5 torr

(Conditions for Forming Electrode Layer 317)
Raw material: Al
Deposition condition: Deposition temperature/deposition pressure=300° C./1e-5 torr

### Example 4

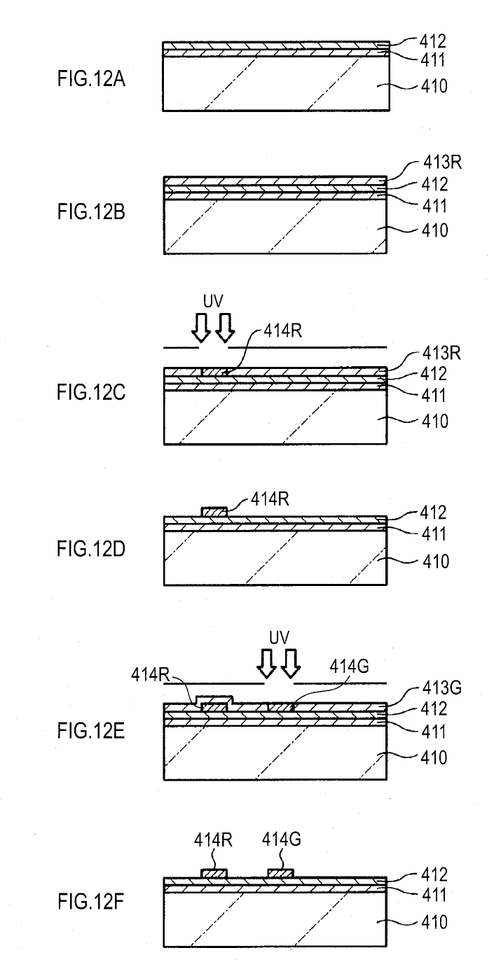

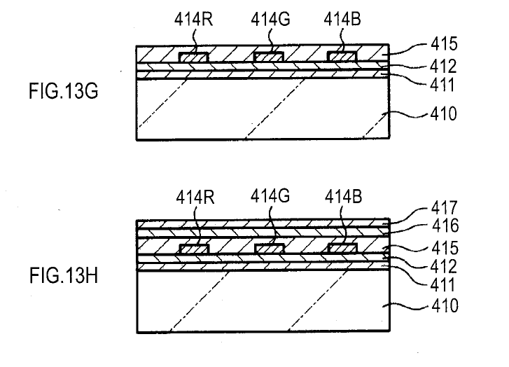

Example 4 is particularly a specific example where acrylcarbazole provided with radical reactivity was used as the host material of a light-emitting material, a fluorescent dye as the guest material thereof, and benzophenone as a radical initiator. Hereinafter, Example 4 will be explained with reference to FIG. 12 to FIG. 13.

As shown in FIG. 12, on a soda lime glass substrate 410, an ITO layer 411 with a thickness of 100 nm was formed by normal sputtering as a conductive layer having no absorption in the visible region for application of voltage-current. In Example 4, the ITO layer 411 was patterned by photolithography.

Further, a hole transport layer 412 was formed by vacuum deposition under the following conditions. In order to ensure solvent resistance at the time of development in a later step, electrons were emitted from hot filaments during the film production to thereby promote the polymerization reaction.

(Conditions for Forming Hole Transport Layer 412)
Raw material: N,N′-bis(3-methylphenyl)-N,N′-diphenyl-[1,1′-biphenyl]-4,4′-diamine, acrylic-modified (acryl-TPD)
Deposition condition: Deposition temperature/deposition pressure=200° C./1e-5 torr

As shown in FIG. 12B, after forming the hole transport layer 412, a precursor layer 413R to serve as a precursor of a red-light-emitting layer 414R was formed by vacuum deposition under the following conditions. Benzophenone employed as a radical initiator was deposited together with the host material and the guest material.

(Conditions for Forming Precursor Layer 413R)
Raw material: Host material: Carbazole acrylate
Guest material: (4-(di-cyano-methylene)-2-methyl-6-(p-dimethyl-amino-styryl)-4H-pyran) (DCM)
Initiator material: Benzophenone
Deposition condition: Deposition temperature/deposition pressure=200° C./1e-5 torr

As shown in FIG. 12C, after forming the precursor layer 413R, a desired region of the precursor layer 413R was exposed to UV irradiation using a mask so as to decompose the radical initiator to generate free radicals. The UV-irradiated region of the precursor layer 413R undergoes a radical polymerization reaction and is thus polymerized.

As shown in FIG. 12D, a non-polymerized region was removed by dissolution with an organic solvent to form a patterned red-light-emitting layer 414R.

As shown in FIG. 12E, a precursor layer 413G to serve as a precursor of a green-light-emitting layer 414G was formed under the following conditions. Benzophenone employed as a radical initiator was deposited together with the host material and the guest material.

(Conditions for Forming Precursor Layer 413G)
Raw material: Host material: Carbazole acrylate
Guest material: Quinacridone
Initiator material: Benzophenone
Deposition condition: Deposition temperature/deposition pressure=200° C./1e-5 torr

After forming the precursor layer 413G, a desired region of the precursor layer 413G was exposed to UV irradiation using a mask so as to decompose the radical initiator contained in the precursor layer 413G to generate free radicals.

Further, as shown in FIG. 12F, a non-polymerized region was removed by dissolution using an organic solvent to form a patterned red-light-emitting layer 414G.

As shown in FIG. 13G, a precursor layer to serve as a precursor of a blue-light-emitting layer 414B was further formed on the hole transport layer 412, the red-light-emitting layer 414R, and the green-light-emitting layer 414G under the following conditions. Subsequently, an electron transport layer 415 was formed in a desired region under the following conditions.

(Conditions for Forming Precursor Layer of Blue-Light-Emitting Layer 414B)
Raw material: Host material: Carbazole acrylate
Guest material: Perylene
Initiator material: Benzophenone
Deposition condition: Deposition temperature/deposition pressure=200° C./1e-5 torr

(Conditions for Forming Electron Transport Layer 415)
Raw material: Quinolinol aluminum complex; tris(8-quinolinolate)aluminum(III) (Alq3)
Deposition condition: Deposition temperature/deposition pressure=200° C./1e-5 torr

Further, as shown in FIG. 13H, an electron injection layer 416 and an electrode layer 417 to serve as the upper electrode were formed in a desired region under the following conditions. A display device was thus completed.

(Conditions for Forming Electron Injection Layer 416)
Raw material: LiF
Deposition condition: Deposition temperature/deposition pressure=300° C./1e-5 torr

(Conditions for Forming Electrode Layer 417)
Raw material: Al
Deposition condition: Deposition temperature/deposition pressure=200° C./1e-5 torr

### Example 5

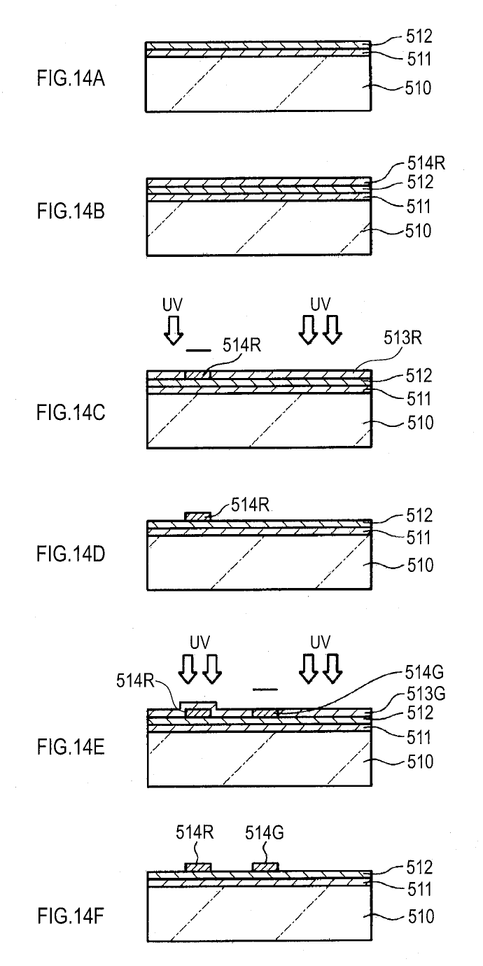

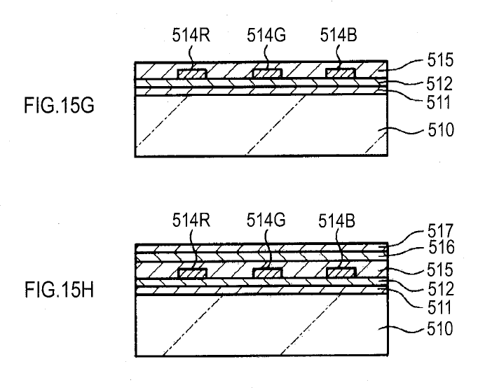

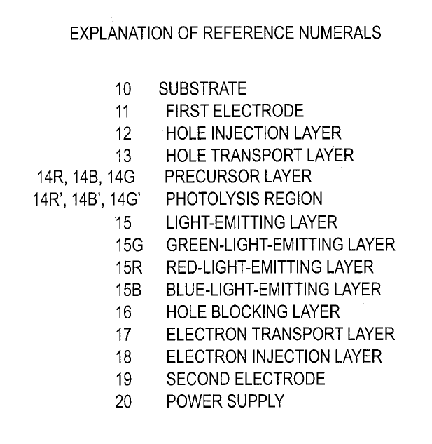

Example 5 is particularly a specific example where a display device was produced using acrylcarbazole having radical-polymerization reactivity as the host material of a light-emitting material, an Ir dye as the guest material thereof, and o-quinonediazide as an acid generator. Hereinafter, Example 5 will be explained with reference to FIG. 14 to FIG. 15.

As shown in FIG. 14, on a soda lime glass substrate 510, an ITO layer 511 with a thickness of 100 nm was formed by sputtering as a conductive layer having no absorption in the visible region for application of voltage-current. In Example 5, the ITO layer 511 was not patterned.

Further, a hole transport layer 512 was formed by vacuum deposition under the following conditions. In order to ensure solvent resistance at the time of development in a later step, electrons were emitted from hot filaments during the film production to thereby promote the polymerization reaction.

(Conditions for Forming Hole Transport Layer 512)
Raw material: N,N′-bis(3-methylphenyl)-N,N′-diphenyl-[1,1′-biphenyl]-4,4′-diamine, acrylic-modified (acryl-TPD)
Deposition condition: Deposition temperature/deposition pressure=200° C./1e-5 torr

As shown in FIG. 14B, after forming the hole transport layer 512, a red-light-emitting layer 514R was formed by vacuum deposition under the following conditions. Specifically, electron beam irradiation was performed to polymerize the light-emitting material. o-Quinonediazide employed as an acid generator, which generates an acid in response to UV irradiation in a later step, was deposited together with the host material and the guest material.

(Conditions for Forming Red-Light-Emitting Layer 514R)
Raw material: Host material: Carbazole acrylate
Guest material: Tris(1-phenylisoquinoline)iridium(III)
Acid generator: o-Quinonediazide
Deposition condition: Deposition temperature/deposition pressure=200° C./1e-5 torr

As shown in FIG. 14C, after forming the red-color-emitting layer 514R, a desired region of the red-color-emitting layer 514R was exposed to UV irradiation using a mask in order to decompose the acid generator to generate acids. The UV-irradiated region of the red-color-emitting layer 514R undergoes a decomposition reaction and is thus depolymerized.

As shown in FIG. 14D, a photolysis region 513R was removed by dissolution with an organic solvent to pattern the red-light-emitting layer 514R.

As shown in FIG. 14E, a green-light-emitting layer 514G was formed by vacuum deposition under the following conditions. Specifically, electron beam irradiation was performed to polymerize the light-emitting material. The acid generator o-quinonediazide was deposited together with the host material and the guest material.

(Conditions for Forming Green-Light-Emitting Layer 514G)
Raw material: Host material: Carbazole acrylate
Guest material: Tris(2-phenylpyridine)iridium(III)
Acid generator: o-Quinonediazide
Deposition condition: Deposition temperature/deposition pressure=200° C./1e-5 torr

After forming the green-color-emitting layer 514G, a desired region of the green-color-emitting layer 514G was exposed to UV irradiation using a mask in order to decompose the acid generator to generate acids.

Further, as shown in FIG. 14F, a photolysis region 513R was removed by dissolution with an organic solvent to pattern the green-light-emitting layer 514G.

As shown in FIG. 15G, a blue-light-emitting layer 514B was further formed on the hole transport layer 512, the red-light-emitting layer 514R, and the green-light-emitting layer 514G, and then the same steps as shown in FIG. 14C to FIG. 14D were successively performed to pattern the blue-light-emitting layer 514B. Subsequently, an electron transport layer 515 was further formed in a desired region under the following conditions.

(Conditions for Forming Blue-Light-Emitting Layer 514B)
Raw material: Host material: Carbazole acrylate
Guest material: Bis(3,5-difluoro-2-(2-pyridyl)phenyl-(2-carboxypyridyl)iridium(III)
Acid generator: o-Quinonediazide
Deposition condition: Deposition temperature/deposition pressure=180° C./1e-5 torr

(Conditions for Forming Electron Transport Layer 515)
Raw material: Quinolinol aluminum complex; (tris(8-quinolinolate)aluminum(III) (Alq3)
Deposition conditions: Deposition temperature/deposition pressure=200° C./1e-5 torr

Further, as shown in FIG. 15H, an electron injection layer 516 and an electrode layer 517 to serve as the upper electrode were formed in a desired region under the following conditions. A display device was thus completed.

(Conditions for Forming Electron Injection Layer 516)
Raw material: LiF
Deposition condition: Deposition temperature/deposition pressure=300° C./1e-5 torr

(Conditions for Forming Electrode Layer 517)
Raw material: Al
Deposition condition: Deposition temperature/deposition pressure=200° C./1e-5 torr

The colors of light emitted by the light-emitting layers are not limited to red, blue, and green. Further, although display device production methods in which light-emitting layers for three different colors are formed have been explained above, the invention is also applicable to a method for producing a display device that has light-emitting layers for one or two colors or light-emitting layers for four or more colors.

Further, for example, values, structures, materials, and the like mentioned in the above embodiments and examples are mere examples, and different values, structures, materials, and the like may also be employed as required.

The embodiments make it possible to achieve high light-emission efficiency and excellent video characteristics in a simple way.

It should be understood that various changes and modifications to the presently preferred embodiments described herein will be apparent to those skilled in the art. Such changes and modifications can be made without departing from the spirit and scope of the present invention and without diminishing its intended advantages. It is therefore intended that such changes and modifications be covered by the appended claims.

1-32. (canceled)

33. A method for producing a display device including a first electrode, a second electrode, and at least one organic layer that is provided between the first electrode and the second electrode and at least has a light-emitting layer, the method comprising:
the light-emitting layer is formed through steps of
forming a composition layer including a radical initiator and a light-emitting material having radical-polymerization reactivity,
exciting the composition layer to form in the composition layer a polymerized region where the composition layer is polymerized, and
removing the composition layer except in the polymerized region.

34. A method for producing a display device according to claim 33, wherein:
the composition layer is excited by UV irradiation, electron beam irradiation, ion irradiation, or X-ray irradiation.

35. A method for producing a display device according to claim 33, wherein:
the light-emitting material includes a host material and a guest material,
the host material being an organic material including an organic material that allows hole-electron recombination and has a radically reactive functional group introduced thereinto, and
the guest material being an organic material that emits light when excited molecules are deactivated.

36. A method for producing a display device according to claim 35, wherein:
the guest material is an organic material having a radically reactive functional group introduced thereinto.

37. A method for producing a display device according to claim 35, wherein:
the host material has one radically reactive functional group.

38. A method for producing a display device according to claim 33, wherein:
the composition layer except in the polymerized region is removed by heating.

39. A method for producing a display device according to claim 35, wherein:
the guest material is a fluorescent material or a phosphorescent material.

40. A method for producing a display device according to claim 35, wherein:
the guest material is a fluorescent material.

41. A method for producing a display device according to claim 33, wherein:
a layer underneath the light-emitting layer is formed of a material having a polymerization reactivity, and
the method for producing a display device further comprises polymerizing the layer underneath the light-emitting layer at the time of forming said layer underneath the light-emitting layer.

42. A method for producing a display device according to claim 33, wherein:
an additional light-emitting layer is formed through steps of:
forming, on the light-emitting layer and a layer underneath the light-emitting layer, an additional composition layer including a radical initiator and a light-emitting material having radical-polymerization reactivity,
exciting the additional composition layer to form a polymerized region where the additional composition layer is polymerized,
exciting the additional composition layer to form a polymerized region where the additional composition layer is polymerized, and
removing the additional composition layer except in the polymerized region.

43. A method for producing a display device including a first electrode, a second electrode, and at least one organic layer that is provided between the first electrode and second electrode and at least has a light-emitting layer, the method comprising forming the light-emitting layer by:
forming a composition layer including an acid generator and a light-emitting material that is polymerized,
exciting the composition layer to form in the composition layer a depolymerized region where the light-emitting material is depolymerized, and
removing the depolymerized region.

44. A method for producing a display device according to claim 43, wherein:
the composition layer is excited by UV irradiation, electron beam irradiation, ion irradiation, or X-ray irradiation.

45. A method for producing a display device according to claim 43, wherein:
the light-emitting material includes a host material and a guest material,
the host material being an organic material including an organic material that allows hole-electron recombination and has a radically reactive functional group introduced thereinto, and
the guest material being an organic material that emits light when excited molecules are deactivated.

46. A method for producing a display device according to claim 45, wherein:
the guest material is an organic material having a radically reactive functional group introduced thereinto.

47. A method for producing a display device according to claim 45, wherein:
the host material has one radically reactive functional group.

48. A method for producing a display device according to claim 45, wherein:
the guest material is a fluorescent material or a phosphorescent material.

49. A method for producing a display device according to claim 45, wherein:
the guest material is a fluorescent material.

50. A method for producing a display device according to claim 43, wherein:
a layer underneath the light-emitting layer is formed of a material having polymerization reactivity, and
the method further comprises polymerizing the layer underneath the light-emitting layer at the time of forming said layer underneath the light-emitting layer.

51. A method for producing a display device according to claim 43, wherein:
an additional light-emitting layer is formed through steps of:
forming, on the light-emitting layer and a layer underneath the light-emitting layer, an additional composition layer formed of a composition layer including an acid generator and a light-emitting material that is polymerized,
exciting the additional composition layer to form in the composition layer a depolymerized region where the light-emitting material is depolymerized, and
removing the additional composition layer except in the depolymerized region.

52. A composition for producing a display device, the composition comprising:
a radical initiator; and
a light-emitting material having radical-polymerization reactivity.

53. A composition for producing a display device according to claim 52, wherein:
the light-emitting material includes a host material and a guest material,
the host material being an organic material including an organic material that allows hole-electron recombination and has a radically reactive functional group introduced thereinto, and
the guest material being an organic material that emits light when excited molecules are deactivated.

54. A composition for producing a display device according to claim 53, wherein:
the guest material is an organic material having a radically reactive functional group introduced thereinto.

55. A composition for producing a display device according to claim 53, wherein:
the host material has one radically reactive functional group.

56. A composition for producing a display device according to claim 53, wherein:
the guest material is a fluorescent material or a phosphorescent material.

57. A composition for producing a display device according to claim 53, wherein:
the guest material is a fluorescent material.

58. A composition for producing a display device, the composition comprising:
an acidolytic agent; and
a light-emitting material having radical-polymerization reactivity.

59. A composition for producing a display device according to claim 58, wherein:
the light-emitting material includes a host material and a guest material,
the host material being an organic material including an organic material that allows hole-electron recombination and has a radically reactive functional group introduced thereinto, and
the guest material being an organic material that emits light when excited molecules are deactivated.

60. A composition for producing a display device according to claim 59, wherein:
the guest material is an organic material having a radically reactive functional group introduced thereinto.

61. A composition for producing a display device according to claim 59, wherein:
the host material has one radically reactive functional group.

62. A composition for producing a display device according to claim 59, wherein:
the guest material is a fluorescent material or a phosphorescent material.

63. A composition for producing a display device according to claim 59, wherein: the guest material is a fluorescent material.

64. A display device comprising:
a first electrode;
a second electrode; and
at least one organic layer that is provided between the first electrode and the second electrode and at least has a light-emitting layer, wherein:
the light-emitting layer includes a polymer compound with a structure containing a repeating unit derived from a light-emitting material having radical-polymerization reactivity.
